(19) United States
(12) Patent Application Publication
(10) Pub. No.: US 2025/0365989 A1
(43) Pub. Date: Nov. 27, 2025

(54) MEMORY STACK AND MEMORY MEDIA INCLUDING STACKED MEMORY CHIPS

(71) Applicant: SK hynix Inc., Gyeonggi-do (KR)

(72) Inventor: Jae Yong KANG, Gyeonggi-do (KR)

(21) Appl. No.: 19/051,188

(22) Filed: Feb. 12, 2025

(30) Foreign Application Priority Data
May 21, 2024 (KR) 10-2024-0065741

(51) Int. Cl. H10B 80/00; H01L 25/065

(52) U.S. Cl. CPC H10B 80/00; H01L 25/0657; H01L 2225/06506; H01L 2225/06562

(57) ABSTRACT

A memory media includes a first memory chip stacked over a substrate, a second memory chip stacked over the first memory chip, and a third memory chip stacked over the second memory chip. The first memory chip, the second memory chip, and the third memory chip are stacked in a staircase. Each of the first memory chip, the second memory chip, and the third memory chip includes outer chip pads disposed to form an outer row which is adjacent to a first edge; and inner chip pads disposed to form an inner row which is spaced apart from the first edge. The third memory chip is stacked over the second memory chip to expose the outer chip pads of the second memory chip and to cover the inner chip pads of the second memory chip.

### CROSS-REFERENCE TO RELATED APPLICATIONS

The present application claims priority under 35 U.S.C 119 (a) to Korean Patent Application No. 10-2024-0065741, filed on May 21, 2024, which is incorporated herein by reference in its entirety.

### BACKGROUND

### 1. Field

Embodiments of the present disclosure generally relate to a memory system including stacked memory chips.

### 2. Description of the Related Art

A memory system may include a plurality of memory chips stacked therein. The memory system has been proposed to increase the integration degree of memory devices.

### SUMMARY

Embodiments of the present disclosure are directed to a memory stack and a memory media including memory chips that are stacked such that the inner chip pads of the memory chips are covered.

Embodiments of the present disclosure are directed to a circuit that may electrically connect or disconnect an outer chip pad and an inner drive circuit to or from each other according to a mode setting signal.

In accordance with an embodiment of the present disclosure, a memory media includes a first memory chip stacked over a substrate, a second memory chip stacked over the first memory chip, and a third memory chip stacked over the second memory chip. The first memory chip, the second memory chip, and the third memory chip are stacked in a staircase. Each of the first memory chip, the second memory chip, and the third memory chip includes outer chip pads disposed to form an outer row which is adjacent to a first edge; and inner chip pads disposed to form an inner row which is spaced apart from the first edge. The third memory chip is stacked over the second memory chip to expose the outer chip pads of the second memory chip and to cover the inner chip pads of the second memory chip.

In accordance with another embodiment of the present disclosure, a memory stack includes a first memory chip, a second memory chip stacked over the first memory chip, a third memory chip stacked over the second memory chip, and a fourth memory chip stacked over the third memory chip. The first memory chip, the second memory chip, the third memory chip, and the fourth memory chip are stacked in a staircase. Each of the first to fourth memory chips includes outer chip pads disposed to form an outer row which is adjacent to a first edge; and inner chip pads disposed to form an inner row which is spaced apart from the first edge. The third memory chip is stacked over the second memory chip to expose the outer chip pads of the second memory chip and to cover the inner chip pads of the second memory chip. The fourth memory chip is stacked over the third memory chip to expose the outer chip pads of the third memory chip and to cover the inner chip pads of the third memory chip.

In accordance with another embodiment of the present disclosure, a memory chip includes a first chip pad; a first drive circuit suitable for electrically connecting the first chip pad to an internal circuit; a second chip pad; a second drive circuit suitable for electrically connecting the second chip pad to the internal circuit; and a chip pad switching circuit. The chip pad switching circuit includes a signal processing unit suitable for receiving a first mode setting signal from an internal mode setting unit and generating a pad switching signal; and a switching circuit unit suitable for receiving the pad switching signal and electrically connecting the first chip pad to the second drive circuit.

### BRIEF DESCRIPTION OF THE DRAWINGS

FIG. 1 is a block diagram schematically illustrating an electronic system in accordance with an embodiment of the present disclosure.

FIG. 2 is a block diagram schematically illustrating a memory media in accordance with an embodiment of the present disclosure.

FIG. 3 is a top view schematically illustrating a memory chip in accordance with an embodiment of the present disclosure.

FIGS. 4A and 4B are perspective and side views schematically illustrating a memory media in accordance with an embodiment of the present disclosure.

FIG. 5A is a side view illustrating an overhang value of a memory stack when all memory chips of the memory stack are stacked such that the inner chip pads of all the memory chips are exposed in accordance with an embodiment of the present disclosure.

FIG. 5B is a side view illustrating an overhang value of a memory stack when a middle lower memory chip and a middle upper memory chip are stacked such that the inner chip pads of the middle lower memory chip and the middle upper memory chip are covered in accordance with an embodiment of the present disclosure.

FIG. 6 is a block diagram schematically illustrating a memory media in accordance with another embodiment of the present disclosure.

FIGS. 7A and 7B are perspective and side views schematically illustrating a memory media in accordance with another embodiment of the present disclosure.

FIG. 8 is a block diagram illustrating an outer drive circuit, an inner drive circuit, and a chip pad switching circuit in accordance with an embodiment of the present disclosure.

FIGS. 9A and 9B are block diagrams illustrating an electrical path through which electrical signals are transferred according to the operation mode of a memory chip.

### DETAILED DESCRIPTION

Embodiments of the present disclosure are described in detail with reference to the accompanying drawings. Specific structural or functional descriptions of embodiments are provided as examples to describe concepts that are disclosed in the present application. Examples or embodiments in accordance with the concepts may be carried out in various forms, and the scope of the present disclosure is not limited to the examples or embodiments described in this specification.

The cross-hatching throughout the figures illustrates corresponding or similar areas between the figures rather than indicating the materials associated with the areas.

When one element is identified as “connected” or “coupled” to another element, the elements may be connected or coupled directly or through an intervening element between the elements. When two elements are identified as “directly connected” or “directly coupled,” one element is directly connected or directly coupled to the other element without an intervening element between the two elements.

When one element is identified as “on,” “over,” “under,” or “beneath” another element, the elements may directly contact each other or an intervening element may be disposed between the elements.

Terms such as “vertical,” “horizontal,” “top,” “bottom,” “above,” “below,” “under,” “beneath,” “over,” “on,” “side,” “upper,” “uppermost,” “lower,” “lowermost,” “front,” “rear,” “left,” “right,” “column,” “row,” “level,” and other terms implying relative spatial relationship or orientation are utilized only for the purpose of ease of description or reference to a drawing and are not otherwise limiting. Other spatial relationships or orientations not shown in the drawings or described in the specification are possible within the scope of the present disclosure.

Terms such as “first” and “second” are used to distinguish between various elements and do not imply size, order, priority, quantity, or importance of the elements. For example, a first element may be named as a second element in one example, and the second element may be named as a first element in another example.

In the description, when an element included in an embodiment is described in singular form, the element may be interpreted to include a plurality of elements performing the same or similar functions.

Concepts are disclosed in conjunction with examples and embodiments as described above. Those skilled in the art will understand that various modifications, additions, and substitutions are possible without departing from the scope and technical concepts of the present disclosure. The embodiments disclosed in the present specification should be considered from an illustrative standpoint and not a restrictive standpoint. Therefore, the scope of the present disclosure is not limited to the above embodiments. All changes within the meaning and range of equivalency of the claims are included within their scope.

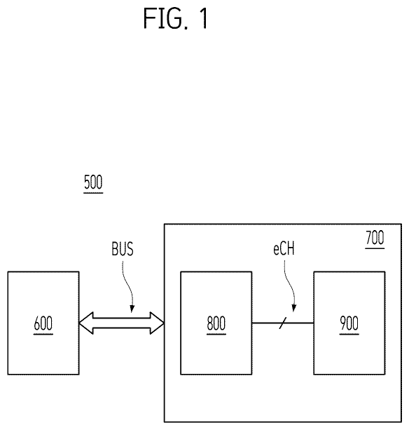

FIG. 1 is a block diagram schematically illustrating an electronic system 500 in accordance with an embodiment of the present disclosure. Referring to FIG. 1, the electronic system 500 may include a host 600 and a memory system 700.

The host 600 may include one among a server, a processor, and a computing system. The processor may include one or more processing units among a plurality of processing units, such as a Central Processing Unit (CPU), an Application Processor (AP), a Micro Control Unit (MCU), and the like. The electronic system 500 may further include a bus BUS that electrically connects the host 600 and the memory system 700. The bus BUS may include, for example, a Compute express Link (CXL) channel. The host 600 may communicate with the memory system 700 through the bus BUS.

The memory system 700 may include a memory controller 800 and a memory media 900. The memory controller 800 may receive various signals and data from the host 600 and transfer the signals and data to the memory media 900. The memory controller 800 may receive data from the memory media 900 and transfer the received data to the host 600. The memory media 900 may store data therein. The memory system 700 may further include external channels eCH that electrically connect the memory controller 800 to the memory media 900. The memory controller 800 may communicate with the memory media 900 through the external channels eCH.

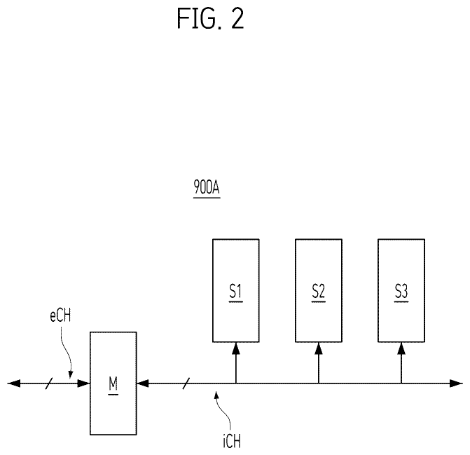

FIG. 2 is a block diagram schematically illustrating a memory media 900A in accordance with an embodiment of the present disclosure. Referring to FIG. 2, the memory media 900A may include one master memory chip M and a plurality of slave memory chips S1 to S3. In the illustrated example of FIG. 2, the plurality of slave memory chips includes three slave memory chips S1 to S3.

The master memory chip M may communicate with each of the slave memory chips S1 to S3 through internal channels ICH. The slave memory chips S1 to S3 may communicate with the memory controller 800 through the internal channels iCH, the master memory chip M, and the external channels eCH. The memory media 900A may be provided in a module form.

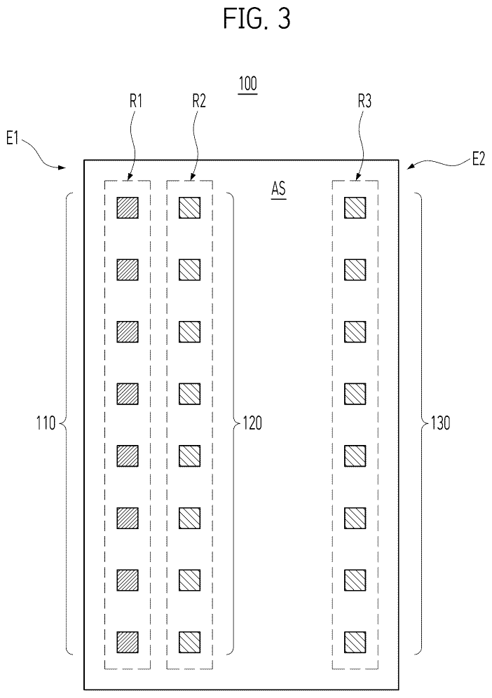

FIG. 3 is a top view schematically illustrating a memory chip 100 in accordance with an embodiment of the present disclosure. The memory chip 100 may be one of the master memory chip M and the slave memory chips S1 to S3 illustrated in FIG. 2. The memory chip 100 may include outer chip pads 110, inner chip pads 120, and power chip pads 130 that are disposed on an active surface AS. The outer chip pads 110 may be disposed adjacent to a first edge E1 of the active surface AS. The inner chip pads 120 may be disposed to be spaced apart from the first edge E1 of the active surface AS. The outer chip pads 110 may be disposed parallel to each other to form an outer row R1 (or an outer column) that is relatively closer to the first edge E1 than the inner chip pads 120. The inner chip pads 120 may be disposed parallel to each other to form an inner row R2 (or an inner column) which is relatively farther from the first edge E1 than the outer chip pads 110. The outer row R1 may be parallel to the inner row R2. The power chip pads 130 may be disposed adjacent to a second edge E2. The power chip pads 130 may be disposed parallel to each other to form a rear row R3 (or a rear column) which is close to the second edge E2. The first edge E1 may be opposite to the second edge E2.

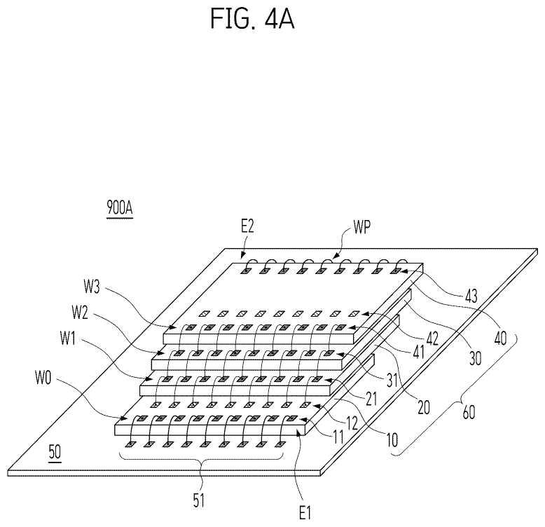

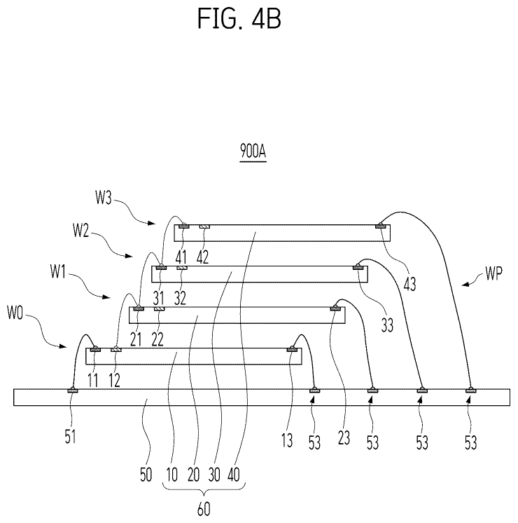

FIGS. 4A and 4B are perspective and side views schematically illustrating a memory media 900A in accordance with an embodiment of the present disclosure. Referring to FIGS. 4A and 4B, the memory media 900A may include a memory stack 60 which is mounted over a substrate 50. The memory stack 60 may include a plurality of memory chips 10, 20, 30, and 40 that are offset-stacked in a staircase. For example, the memory stack 60 may include a lowermost memory chip 10, a middle lower memory chip 20, a middle upper memory chip 30, and an uppermost memory chip 40. In some embodiments, the lowermost memory chip 10 may be a master memory chip M. The middle lower memory chip 20, the middle upper memory chip 30, and the uppermost memory chip 40 may be slave memory chips S1 to S3.

The substrate 50 may include one of a printed circuit board (PCB), an interposer, and a silicon redistribution layer. The substrate 50 may include substrate pads 51 and 53. The substrate pads 51 and 53 may include signal substrate pads 51 and power substrate pads 53. The signal substrate pads 51 may be disposed close to the first edges E1 of the memory chips 10, 20, 30, and 40. The power substrate pads 53 may be disposed close to the second edges E2 of the memory chips 10, 20, 30, and 40. The signal substrate pads 51 may provide and transfer, to the memory chips 10, 20, 30, and 40, clock signals, command signals, address signals, data signals, strobe signals, chip identification signals, and other signals. The power substrate pads 53 may provide and transfer, to the memory chips 10, 20, 30, and 40, a power voltage VDD, ground voltages GND and VSS, a data voltage VDDQ, an internal voltage VDDi, and other various voltages.

The signal substrate pads 51 may be electrically connected to the outer chip pads 11 of the lowermost memory chip 10 through substrate wires W0, respectively. The inner chip pads 12 of the lowermost memory chip 10 may be electrically connected to the outer chip pads 21 of the middle lower memory chip 20 through first inter-chip wires W1, respectively. The outer chip pads 21 of the middle lower memory chip 20 may be electrically connected to the outer chip pads 31 of the middle upper memory chip 30 through second inter-chip wires W2, respectively. The outer chip pads 31 of the middle upper memory chip 30 may be electrically connected to the outer chip pads 41 of the uppermost memory chip 40 through third inter-chip wires W3, respectively. The inner chip pads 12 of the lowermost memory chip 10 may be electrically connected to the outer chip pads 21 of the middle lower memory chip 20, the outer chip pads 31 of the middle upper memory chip 30, and the outer chip pads 41 of the uppermost memory chip 40 through the inter-chip wires W1, W2, and W3, respectively. The inner chip pads 12 of the lowermost memory chip 10 (i.e., the master memory chip M) may be electrically connected to the outer chip pads 21, 31, and 41 of the slave memory chips 20, 30, and 40, (i.e., S1 to S3) through the inter-chip wires W1, W2, and W3, respectively.

The inner chip pads 22 of the middle lower memory chip 20 may vertically overlap with and be covered with the middle upper memory chip 30. The inner chip pads 32 of the middle upper memory chip 30 may vertically overlap with and be covered with the uppermost memory chip 40. The middle upper memory chip 30 may be stacked over the middle lower memory chip 20 to cover the inner chip pads 22 of the middle lower memory chip 20. The uppermost memory chip 40 may be stacked over the middle upper memory chip 30 to cover the inner chip pads 32 of the middle upper memory chip 30. The inner chip pads 22, 32, and 42 of the slave memory chips S1 to S3, i.e., the middle lower memory chip 20, the middle upper memory chip 30, and the uppermost memory chip 40, may not be bonded with wires so as not to be electrically connected to the outside. The covered inner chip pads 22, 32, and 42 of the middle lower memory chip 20, the middle upper memory chip 30, and the uppermost memory chip 40, may be electrically floated (floating state).

The power chip pads 13, 23, 33, and 43 of the memory chips 10, 20, 30, and 40 may be connected to the substrate power pads 53 through power wires WP, respectively.

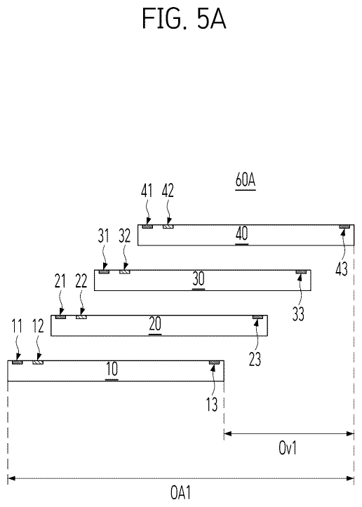

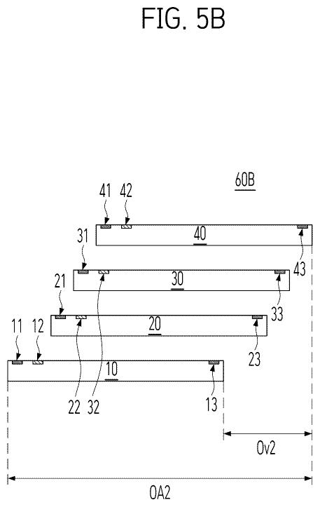

FIG. 5A is a side view illustrating an overhang value Ov1 and an occupied area OA1 of the memory stack 60A when all the memory chips 10, 20, 30, and 40 are stacked such that the inner chip pads 12, 22, 32, and 42 of all the memory chips 10, 20, 30, and 40 are exposed. FIG. 5B is a side view illustrating an overhang value Ov2 and an occupied area OA2 of the memory stack 60B when the middle lower memory chip 20 and the middle upper memory chip 30 are stacked such that the inner chip pads 22 and 32 of the middle lower memory chip 20 and the middle upper memory chip 30 are covered.

Referring to FIG. 5A, when all memory chips 10, 20, 30, and 40 are stacked such that the inner chip pads 12, 22, 32, and 42 of all memory chips 10, 20, 30, and 40 are exposed, the memory chips 10, 20, 30, and 40 of the memory stack 60A may be stacked to have a first overhang value Ov1 and a first occupied area OA1. Referring to FIG. 5B, when the middle lower memory chip 20 and the middle upper memory chip 30 are stacked such that the inner chip pads 22 and 32 of the middle lower memory chip 20 and the middle upper memory chip 30 are covered, the memory chips 10, 20, 30, and 40 of the memory stack 60B may be stacked to have a second overhang value Ov2 and a second occupied area OA2. As illustrated in FIGS. 5A and 5B, the first overhang value Ov1 may be greater than the second overhang value Ov2, and the first occupied area OA1 may be greater than the second occupied area OA2. Accordingly, the memory stack 60B in accordance with the embodiment of the present disclosure can have a reduced occupied area OA2. Also, in the process of bonding the power wires W0 onto the power chip pads 33 and 34 of the middle upper memory chip 30 and the uppermost memory chip 40, the physical and mechanical support structures of the memory stack 60 may be improved.

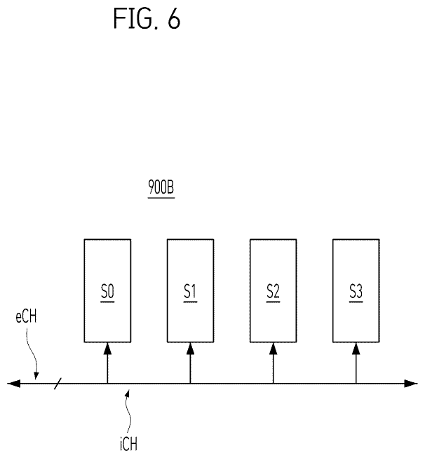

FIG. 6 is a block diagram schematically illustrating a memory media 900B in accordance with another embodiment of the present disclosure. Referring to FIG. 6, the memory media 900B may include a plurality of slave memory chips S0 to S3. Compared to the memory media 900A of FIG. 2, the memory media 900B may not include a master memory chip M. The slave memory chips S0 to S3 may be connected to the external channels eCH through the internal channels ICH. As illustrated in FIG. 6, the external channels eCH may be the same as the internal channels ICH. The slave memory chips S0 to S3 may be independently coupled to the memory controller 800. For example, the memory controller 800 may directly and individually communicate with the slave memory chips S0 to S3.

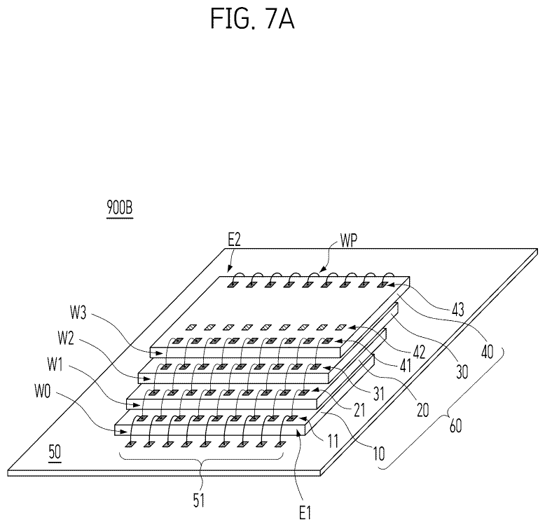

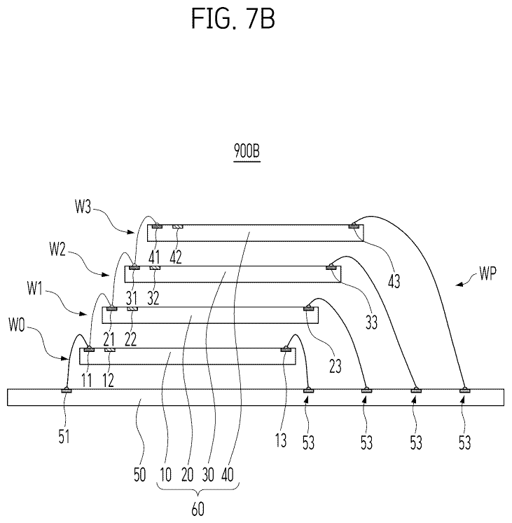

FIGS. 7A and 7B are perspective and side views schematically illustrating a memory media 900B in accordance with another embodiment of the present disclosure. Referring to FIGS. 7A and 7B, the memory media 900B may include a memory stack 60 which is mounted over a substrate 50. The memory stack 60 may include a plurality of memory chips 10, 20, 30, and 40 that are offset-stacked in a staircase. For example, the memory stack 60 may include a lowermost memory chip 10, a middle lower memory chip 20, a middle upper memory chip 30, and an uppermost memory chip 40. In some embodiments, the lowermost memory chip 10, the middle lower memory chip 20, the middle upper memory chip 30, and the uppermost memory chip 40 may all be slave memory chips S0 to S3.

The signal substrate pads 51 may be electrically connected to the outer chip pads 11 of the lowermost memory chip 10 through the substrate wires W0, respectively.

The outer chip pads 11 of the lowermost memory chip 10 may be electrically connected to the outer chip pads 21 of the middle lower memory chip 20 through the first inter-chip wires W1, respectively. The outer chip pads 21 of the middle lower memory chip 20 may be electrically connected to the outer chip pads 31 of the middle upper memory chip 30 through the second inter-chip wires W2, respectively. The outer chip pads 31 of the middle upper memory chip 30 may be electrically connected to the outer chip pads 41 of the uppermost memory chip 40 through the third inter-chip wires W3, respectively. The outer chip pads 11, 21, 31, and 41 of all memory chips 10, 20, 30 and 40 may be connected to each other through the inter-chip wires W1 to W3.

The inner chip pads 12 of the lowermost memory chip 10 may vertically overlap with and be covered with the middle lower memory chip 20. The inner chip pads 22 of the middle lower memory chip 20 may vertically overlap with and be covered with the middle upper memory chip 30. The inner chip pads 32 of the middle upper memory chip 30 may vertically overlap with and be covered with the uppermost memory chip 40. The middle lower memory chip 20 may be stacked over the lowermost memory chip 10 to cover the inner chip pads 21 of the lowermost memory chip 10. The middle upper memory chip 30 may be stacked over the middle lower memory chip 20 to cover the inner chip pads 22 of the middle lower memory chip 20. The uppermost memory chip 40 may be stacked over the middle upper memory chip 30 to cover the inner chip pads 32 of the middle upper memory chip 30. The inner chip pads 12, 22, 32, and 42 of all memory chips 10, 20, 30, and 40 may not be bonded with wires so as not to be electrically connected to the outside. All covered inner chip pads 10, 20, 30, and 40 may be electrically floated. (floating state)

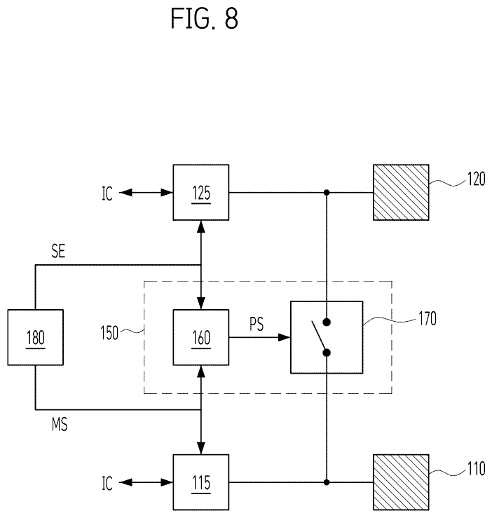

FIG. 8 is a block diagram illustrating an outer chip pad 110, an outer drive circuit 115, an inner chip pad 120, an inner drive circuit 125, and a chip pad switching circuit 150 in accordance with an embodiment of the present disclosure.

The chip pad switching circuit 150 may electrically connect or disconnect the outer chip pad 110 and the inner drive circuit 125 to or from each other. The chip pad switching circuit 150 may electrically connect or disconnect the outer chip pad 110 and the inner chip pad 120 to or from each other. For example, when the memory chip 100 operates in a master mode, the chip pad switching circuit 150 may electrically disconnect the outer chip pad 110 and the inner drive circuit 125 from each other. When the memory chip 100 operates in a slave mode, the chip pad switching circuit 150 may electrically connect the outer chip pad 110 and the inner drive circuit 125 to each other. The chip pad switching circuit 150 may include a signal processing unit 160 and a switching circuit 170. Therefore, in the master mode, the outer chip pad 110 and the inner chip pad 120 may not be electrically connected, whereas in the slave mode, the outer chip pad 110 and the inner chip pad 120 may be electrically connected.

The outer drive circuit 115 may be electrically disposed between an internal circuit IC and the outer chip pad 110. The inner drive circuit 125 may be electrically disposed between the internal circuit IC and the inner chip pad 120. The internal circuit IC may include an input and output (input/output) circuit.

The outer drive circuit 115 may be activated or deactivated by receiving a mode setting signal MS from an internal mode setting unit 180. For example, when the mode setting signal MS is an enable signal (e.g., logic high: 1), the outer drive circuit 115 may be activated to electrically connect the outer chip pad 110 and the internal circuit IC to each other. When the mode setting signal MS is a disable signal (e.g., logic low: 0), the outer drive circuit 115 may be deactivated to electrically disconnect the outer chip pad 110 and the internal circuit IC. The mode setting signal MS may be a master enable signal. When the mode setting signal MS is an enable signal, the memory chip 100 may operate in the master mode. The mode setting signal MS may be one of a chip identification signal CID, a master identification signal, and a mode register signal MRS. The mode setting signal MS may be generated from the mode setting unit 180 inside the memory chip 100 based on the master chip identification signal which is provided from the memory controller 800.

When the mode setting signal MS is an enable signal, that is, when the outer drive circuit 115 is activated, the chip pad switching circuit 150 may electrically disconnect the outer chip pad 110 and the inner drive circuit 125 from each other. The inner chip pad 110 and the outer chip pad 120 may exist electrically independently. When the mode setting signal MS is a disable signal, the outer drive circuit 115 may be deactivated, and the chip pad switching circuit 150 may electrically connect the outer chip pad 110 and the inner drive circuit 125 to each other directly.

The inner drive circuit 125 may be activated by receiving a slave enable signal SE from the mode setting unit 180. Typically, the slave enable signal SE may always be an enable signal (e.g., logic high: 1). Therefore, according to an embodiment of the present disclosure, the slave enable signal SE may be omitted. Even though the slave enable signal SE is omitted, the inner drive circuit 125 may always be activated. The inner drive circuit 125 may electrically connect the inner chip pad 120 and the internal circuit IC to each other.

The signal processing unit 160 may receive and process the mode setting signal MS and the slave enable signal SE to generate a pad switching signal PS. For example, when the mode setting signal MS is an enable signal, the pad switching signal PS may be a disconnect signal. When the mode setting signal MS is a disable signal, the pad switching signal PS may be a connect signal.

The pad switching signal PS may be provided to the switching circuit 170. The switching circuit 170 may electrically connect or disconnect the outer chip pad 110 and the inner drive circuit 125 according to the pad switching signal PS. According to an embodiment of the present disclosure, the switching circuit 170 may include a drive circuit or a buffering circuit. The pad switching signal PS may connect or disconnect the outer chip pad 110 and the inner drive circuit 125 by activating or deactivating the drive circuit or the buffering circuit.

Therefore, when the memory chip 100 operates in the master mode, the mode setting signal MS may be an enable signal, and the electrical connection between the outer chip pad 110 and the inner drive circuit 125 may be disconnected. When the memory chip 100 operates in the slave mode, the mode setting signal MS may be a disable signal, and the outer chip pad 110 and the inner drive circuit 125 may be electrically connected. For example, when the mode setting signal MS is an enable signal, the pad switching signal PS may be a disconnect signal. When the mode setting signal MS is a disable signal, the pad switching signal PS may be a connect signal.

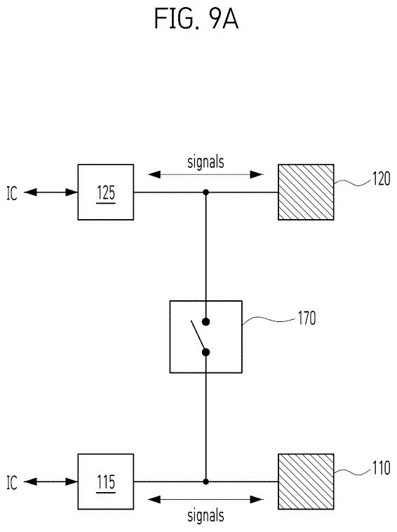

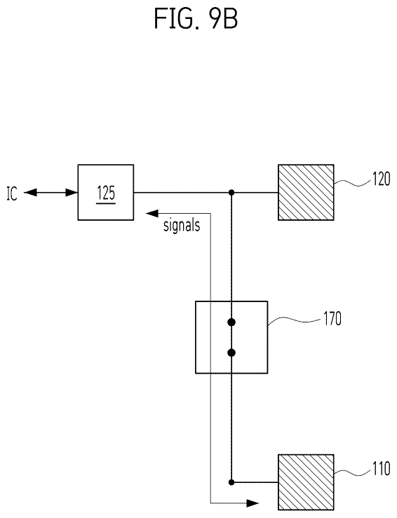

FIGS. 9A and 9B are block diagrams illustrating an electrical path through which electrical signals are transferred according to the operation mode of the memory chip 100.

Referring to FIG. 9A, when the memory chip 100 operates in the master mode, the switching circuit 170 of the chip pad switching circuit 150 may electrically disconnect the outer chip pad 110 and the inner drive circuit 125 from each other. Accordingly, the outer chip pad 110 may be electrically connected to the inner circuit IC through the outer drive circuit 115, and the inner chip pad 120 may be electrically connected to and communicated with the inner circuit IC through the inner drive circuit 125.

Referring to FIG. 9B, when the memory chip 100 operates in the slave mode, the switching circuit 170 of the chip pad switching circuit 150 may electrically connect the outer chip pad 110 and the inner drive circuit 125 directly. Accordingly, the outer drive circuit 115 may be deactivated, and the outer chip pad 110 and the inner drive circuit 125 may be electrically connected. The outer chip pad 110 and the inner circuit IC may be electrically connected and communicate with each other through the inner drive circuit 125.

According to an embodiment of the present disclosure, the overhang value of the stacked memory chips may be decreased. Therefore, the process stability of the wire bonding process may be improved. The stacking stability of the memory chips may be improved.

While the embodiments of the present disclosure have been described with respect to the specific embodiments, it will be apparent to those skilled in the art that various changes and modifications may be made without departing from the spirit and scope of the present disclosure as defined in the following claims. Furthermore, the embodiments may be combined to form additional embodiments.

What is claimed is:

1. A memory media comprising:
a first memory chip stacked over a substrate;
a second memory chip stacked over the first memory chip; and
a third memory chip stacked over the second memory chip,
wherein the first memory chip, the second memory chip, and the third memory chip are stacked in a staircase,
wherein each of the first memory chip, the second memory chip, and the third memory chip includes:
outer chip pads disposed to form an outer row which is adjacent to a first edge; and
inner chip pads disposed to form an inner row which is spaced apart from the first edge, and
wherein the third memory chip is stacked over the second memory chip to expose the outer chip pads of the second memory chip and to cover the inner chip pads of the second memory chip.

2. The memory media of claim 1, further comprising:
a fourth memory chip stacked over the third memory chip,
wherein the fourth memory chip is stacked over the third memory chip to expose the outer chip pads of the third memory chip and to cover the inner chip pads of the third memory chip.

3. The memory media of claim 2, wherein the outer chip pads of the third memory chip are electrically connected to the outer chip pads of the fourth memory chip, respectively.

4. The memory media of claim 3, wherein the inner chip pads of the fourth memory chip are in a floating state.

5. The memory media of claim 1,
wherein the substrate includes signal substrate pads that are disposed close to first edges of the first to third memory chips, and
wherein the signal substrate pads are electrically connected to the outer chip pads of the first memory chip through substrate wires, respectively.

6. The memory media of claim 5, wherein:
the substrate further includes power substrate pads that are disposed close to second edges of the first to third memory chips,
each of the first to third memory chips further includes power chip pads that are disposed adjacent to the second edges,
the power substrate pads are electrically connected to the power substrate pads of the first to third memory chips through power wires, respectively, and
the first edge and the second edge are facing each other.

7. The memory media of claim 1, wherein the second memory chip is stacked over the first memory chip to expose both of the outer chip pads and the inner chip pads of the first memory chip.

8. The memory media of claim 1, wherein the inner chip pads of the first memory chip are electrically connected to the outer chip pads of the second memory chip through first inter-chip wires, respectively.

9. The memory media of claim 8, wherein the outer chip pads of the second memory chip are electrically connected to the outer chip pads of the third memory chip through second inter-chip wires, respectively.

10. The memory media of claim 1, wherein the second memory chip is stacked over the first memory chip to expose the outer chip pads of the first memory chip and to cover the inner chip pads of the first memory chip.

11. The memory media of claim 10, wherein the outer chip pads of the first memory chip are electrically connected to the outer chip pads of the second memory chip, respectively.

12. A memory stack comprising:
a first memory chip;
a second memory chip stacked over the first memory chip;
a third memory chip stacked over the second memory chip; and
a fourth memory chip stacked over the third memory chip,
wherein the first memory chip, the second memory chip, the third memory chip, and the fourth memory chip are stacked in a staircase,
wherein each of the first to fourth memory chips includes:
outer chip pads disposed to form an outer row which is adjacent to a first edge; and
inner chip pads disposed to form an inner row which is spaced apart from the first edge,
wherein the third memory chip is stacked over the second memory chip to expose the outer chip pads of the second memory chip and to cover the inner chip pads of the second memory chip, and
wherein the fourth memory chip is stacked over the third memory chip to expose the outer chip pads of the third memory chip and to cover the inner chip pads of the third memory chip.

13. The memory stack of claim 12, wherein the second memory chip is stacked over the first memory chip to expose both of the outer chip pads and the inner chip pads of the first memory chip.

14. The memory stack of claim 13, wherein
the inner chip pads of the first memory chip, the outer chip pads of the second memory chip, the outer chip pads of the third memory chip, and the outer chip pads of the fourth memory chip are electrically connected to each other through inter-chip wires.

15. The memory stack of claim 12, wherein the second memory chip is stacked over the first memory chip to expose the outer chip pads of the first memory chip and to cover the inner chip pads of the first memory chip.

16. The memory stack of claim 15, wherein the outer chip pads of the first memory chip, the outer chip pads of the second memory chip, the outer chip pads of the third memory chip, and the outer chip pads of the fourth memory chip are electrically connected to each other through inter-chip wires.

17. A memory chip comprising:
a first chip pad;
a first drive circuit suitable for electrically connecting the first chip pad to an internal circuit;
a second chip pad;
a second drive circuit suitable for electrically connecting the second chip pad to the internal circuit; and
a chip pad switching circuit,
wherein the chip pad switching circuit includes:
a signal processing unit suitable for receiving a first mode setting signal from an internal mode setting unit and generating a pad switching signal; and
a switching circuit unit suitable for receiving the pad switching signal and electrically connecting the first chip pad to the second drive circuit.

18. The memory chip of claim 17, wherein the first mode setting signal deactivates the first drive circuit.

19. The memory chip of claim 17, wherein the first mode setting signal sets the memory chip to operate in either a master mode or a slave mode.

20. The memory chip of claim 17, wherein the switching circuit unit includes a drive circuit.
